(19) United States
(12) Patent Application Publication
(10) Pub. No.: US 2025/0390658 A1
(43) Pub. Date: Dec. 25, 2025

(54) GENERATING AND ANALYZING A LAYOUT OF A SEMICONDUCTOR DEVICE

(71) Applicant: Microchip Technology Incorporated, Chandler, AZ (US)

(72) Inventors: Mandar Ramesh DESHPANDE, Cupertino, CA (US); Claudia Anca DUMITRESCU, Bucuresti (RO); Karthik RAJAN, Tempe, AZ (US)

(21) Appl. No.: 19/200,657

(22) Filed: May 6, 2025

Related U.S. Application Data
(60) Provisional application No. 63/663,685, filed on Jun. 24, 2024.

(51) Int. Cl. G06F 30/392; G06F 30/394; G06F 30/398

(52) U.S. Cl. CPC G06F 30/392; G06F 30/394; G06F 30/398

(57) ABSTRACT

In some implementations, a computing device may generate a layout of a semiconductor device based on one or more parameters regarding the layout of the semiconductor device. The computing device may analyze the layout of the semiconductor device. The computing device may perform iterations of generating the layout and analyzing the layout, wherein the one or more parameters are a first value during a first iteration of the iterations, and wherein the one or more parameters are a second value during a second iteration of the iterations. The computing device may generate a model of the semiconductor device based on performing the iterations. The computing device may provide the model to cause the semiconductor device to be manufactured based on the model.

### RELATED APPLICATION

This application claims priority to U.S. Provisional Patent Application No. 63/663,685 entitled “GENERATING AND ANALYZING A LAYOUT OF A SEMICONDUCTOR DEVICE,” filed Jun. 24, 2024, which is incorporated herein by reference in its entirety.

### FIELD

The present disclosure generally relates to electronic design automation (EDA) for semiconductor devices and, for example, the design and simulation of semiconductor devices.

### BACKGROUND

A semiconductor device may include a power device, such as a power metal oxide semiconductor field effect transistor (MOSFET). A layout of the semiconductor device may be designed before the semiconductor device is manufactured. In some situations, the layout of the semiconductor device may cause unintended consequences on a performance of the semiconductor device due to various factors, such as parasitic metal routing resistance.

### SUMMARY

A method comprising: generating a layout of a semiconductor device based on one or more parameters regarding the layout of the semiconductor device; analyzing the layout of the semiconductor device; performing iterations of generating the layout and analyzing the layout, wherein one or more values, of the one or more parameters, are a first value during a first iteration of the iterations, and wherein the one or more values, of the one or more parameters, are a second value during a second iteration of the iterations; generating a model of the semiconductor device based on performing the iterations; and providing the model of the semiconductor device to a semiconductor manufacturing facility to cause the semiconductor manufacturing facility to manufacture the semiconductor device based on the model.

A system comprising: one or more processing units adapted to: generate a layout of a power semiconductor device based on one or more parameters regarding the layout of the power semiconductor device; analyze the layout of the semiconductor device to determine a characteristic of the power semiconductor device; perform iterations of generating the layout and analyzing the layout, wherein one or more values, of the one or more parameters, are a first value during a first iteration of the iterations, and wherein the one or more values, of the one or more parameters, are a second value during a second iteration of the iterations; generate a model of the power semiconductor device based on performing the iterations; and provide the model of the power semiconductor device to cause the power semiconductor device to be manufactured based on attributes of the model.

A non-transitory computer-readable medium storing a set of instructions, the set of instructions comprising: one or more instructions that, when executed by one or more processors of a computing device, cause the computing device to: generate a layout of a semiconductor device based on one or more parameters regarding the layout of the semiconductor device; analyze the layout of the semiconductor device; perform iterations of generating the layout and analyzing the layout, wherein one or more values, of the one or more parameters, are a first value during a first iteration of the iterations, and wherein the one or more values, of the one or more parameters, are a second value during a second iteration of the iterations; generate a model of the semiconductor device based on performing the iterations; and provide the model to cause the semiconductor device to be manufactured based on the model.

### BRIEF DESCRIPTION OF THE DRAWINGS

FIG. 1 is a diagram of example layouts of a given set of components of a semiconductor device.

FIG. 2 is a diagram of an automated design and fabrication process for semiconductor devices with an optimal layout, in accordance with some implementations described herein.

FIG. 3 is a diagram of an automated determination of an optimal layout of a semiconductor device with a given set of components, in accordance with some implementations described herein.

FIG. 4 is a diagram of example components of one or more devices that may be used to generate and analyze a layout of a semiconductor device.

FIG. 5 is a flowchart of generating a layout of a semiconductor device using techniques described herein, in accordance with some implementations.

### DETAILED DESCRIPTION

The following detailed description of example implementations refers to the accompanying drawings. The same reference numbers in different drawings may identify the same or similar elements.

A layout of a semiconductor device may be designed before the semiconductor device is manufactured. Designing the layout of the semiconductor device may include determining the device area and aspect ratio, a number of pads, determining locations of the pad on the semiconductor device, and metal routing topology, among other examples. Performance and reliability of the semiconductor device and, accordingly, the design of the layout of such semiconductor device may vary with device and package layout implementation choices and constraints due to effects on the semiconductor device. Measures of resistance in the semiconductor device, such as parasitic metal routing resistance, resistance between source and drain pads (also referred to as “on-resistance” or “Ron”), or the like may vary with different potential designs of a given semiconductor device. Excessive resistance within the semiconductor device may degrade performance and/or reliability of the semiconductor device.

Manual procedures to generate a layout of the semiconductor device may involve relatively laborious efforts from engineers or other individuals, and may further yield sub-optimal layouts that exhibit more resistance than optimal layouts. Manually generated layouts may, for example, lead to larger chip area, increased cost, increased resistance, and/or higher power dissipation than optimal layouts that may be generated in accordance with some implementations described herein.

Implementations described herein are directed to optimizing the design of a semiconductor device, where such device specifies a particular set of components (e.g., Field Effect Transistors (FETs), Metal Oxide Semiconductor FETs (MOSFETs), electro-static discharge (ESD) protection devices, diodes, capacitors, or the like), but is variable in terms of factors such as aspect ratio, quantity and location of source and/or drain pads, and metal or wire topology (e.g., where such metals or wires facilitate signals to be sent between components of the semiconductor device), among other potential factors. While examples are described herein in the context of semiconductor devices that include components such as MOSFETs, capacitors, and/or other components, similar concepts are applicable to semiconductor devices that include other types of components.

Implementations described herein may utilize electronic design automation (EDA) tools to utilize artificial intelligence/machine learning (AI/ML) techniques or other automated techniques to generate one or more models that indicate optimal layouts for semiconductor devices, in view of specifications of such semiconductor devices (e.g., specified sets of components of respective semiconductor devices). The layouts may be used as part of a design process (e.g., may be used to guide or inform design teams of an optimal layout), and/or may be used to directly manufacture semiconductor devices in accordance with the optimal layout. For example, the layouts may be provided to a semiconductor manufacturing facility to cause (or instruct) the semiconductor manufacturing facility to manufacture or fabricate one or more semiconductor devices based on the model.

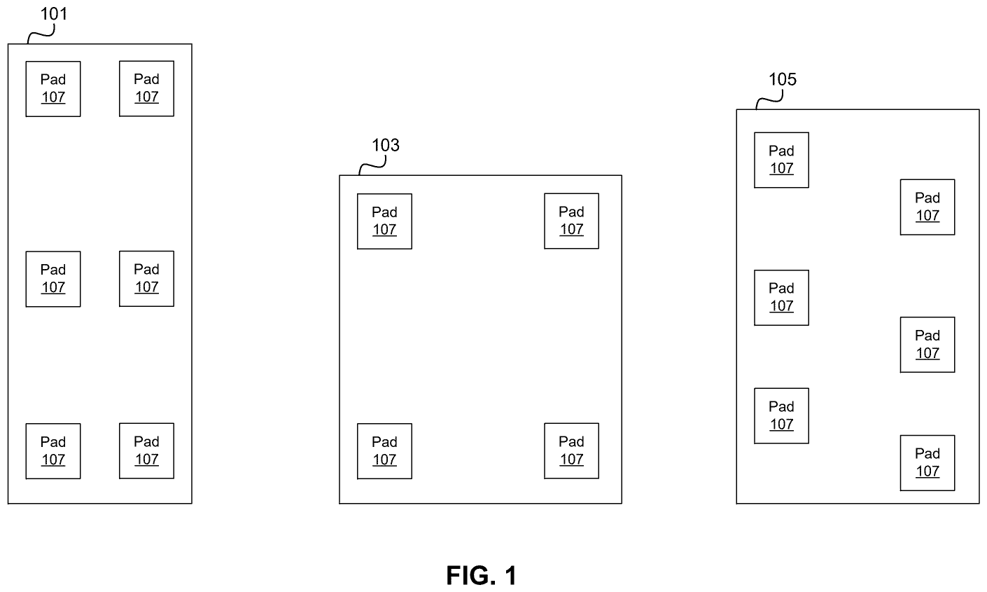

FIG. 1 illustrates, for example, example layouts 101, 103, and 105 of a semiconductor device that includes a particular set of components, such as a specified quantity and/or arrangement of MOSFETs, ESDs, capacitors, or the like. For the sake of clarity, the set of components are not shown in the figure for each example layout.

As shown, each layout may also include a respective set of pads 107, which may include source and/or drain pads that serve to provide electrical power to various components of the semiconductor device. For example, layout 101 may include one arrangement of pads 107, layout 103 may include another arrangement of pads 107, and layout 105 may include yet another arrangement of pads 107. As further illustrated by the figure, different layouts may include different quantities of pads 107. For example, layouts 101 and 105 include six pads 107, while layout 103 includes four pads 107. Further, the locations of pads 107 may be different for each of the different layouts. While each configuration of pads 107 may be sufficient to power the components of the semiconductor device (in each layout 101, 103, or 105), the different pad configurations (e.g., quantity and/or location of pads 107) may, in concert with other factors such as an aspect ratio of each layout, lead to differing amounts of resistance of the semiconductor device.

As further shown, each layout may include a different aspect ratio (e.g., a function of length in two dimensions, such as a length and width of the semiconductor device in accordance with each layout). For example, layout 101 may exhibit a “narrowest” or “longest” aspect ratio, and layout 103 may exhibit a “widest” or “shortest” aspect ratio. That is, the cumulative area of the components (other than pads 107) of the semiconductor device may be approximately the same among the layouts, even though the aspect ratios of such layouts differ. The aspect ratio, in concert with or without other factors (e.g., quantity and/or location of pads 107 and/or metal routing topology) may lead to differing amounts of resistance of the semiconductor device.

As noted above, each layout may be associated with a different metal or conductor routing topology. The metal or conductor routing topology may refer to paths, or otherwise to an arrangement, of metal and/or conductors that connect different components of the semiconductor device to each other, thus facilitating electrical signals to be sent between such different components. The metal or conductor routing topology, in concert with or without other factors (e.g., quantity and/or location of pads 107 and/or aspect ratio) may lead to differing amounts of resistance of the semiconductor device.

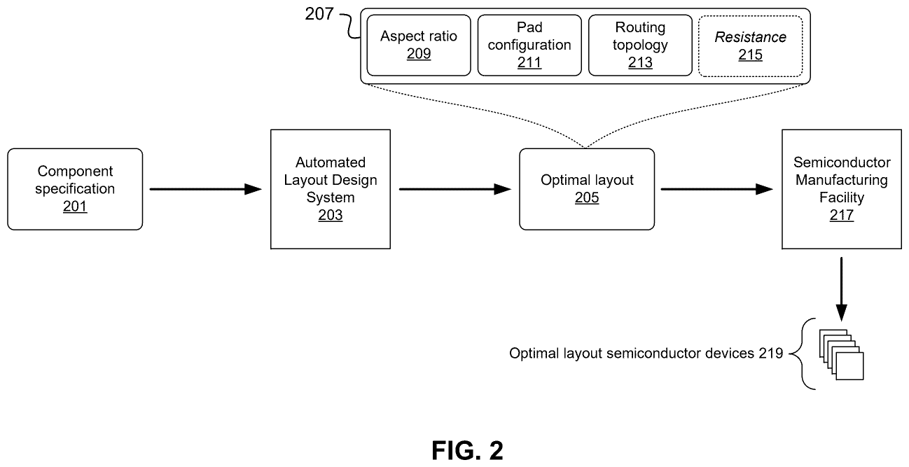

FIG. 2 illustrates an example procedure for generating a set of semiconductor devices, with a specified set of components, that are in accordance with an optimal layout. In the examples described herein, layouts may be “optimal” in terms of resistance (e.g., Ron) of the semiconductor device. An “optimal” resistance may be a lowest possible resistance, may be a resistance that is within a particular range, or may be defined in some other suitable manner.

As shown, component specification 201 may be provided to Automated Layout Design System (ALDS) 203. ALDS 203 may, for example, implement EDA tools and utilize AI/ML techniques to generate optimal layout 205 based on component specification 201. In some examples, ALDS 203 may use a scripting language to generate optimal layout 205. In some examples, the scripting language may include a silicon compiler interface language (SCIL) script. The SCIL script (also referred to as SKILL script) may be used in conjunction with a parameterized cells (PCell) description language. In some examples, the scripting language maybe loaded into the EDA tool using another scripting language, such as a Perl script. As noted above, component specification 201 may specify particular components, such as MOSFETs, ESDs, capacitors, diodes, or other types of components to be included in a semiconductor device. In some implementations, the component specification 201 may specify particular “blocks” or sets of components that are to be placed in a particular arrangement, such as proximate to each other, and/or in particular locations with respect to each other.

As discussed below, ALDS 203 may identify optimal layout 205, given component specification 201. In some implementations, optimal layout 205 may be represented by a particular model, such as a model generated using AI/ML techniques or other suitable automated techniques. Optimal layout 205 may include parameters 207, such as aspect ratio parameter 209, pad configuration parameter 211, routing topology parameter 213, and resistance parameter 215. As noted above, aspect ratio parameter 209 may refer to a length and/or width of a semiconductor device that implements optimal layout 205. Pad configuration parameter 211 may refer to a quantity and/or location of pads, such as source pads and/or drain pads, on the semiconductor device that implements optimal layout 205. Routing topology parameter 213 may indicate locations of particular components on the semiconductor device, as well as paths or locations of metal and/or conductors that connect such components. Resistance parameter 215 may specify an actual or predicted measure of resistance (e.g., Ron) exhibited by a semiconductor device that implements optimal layout 205.

As discussed below, some or all of parameters 207 may be identified by ALDS 203 using AI/ML techniques, which may include iteratively generating and running simulations of potential semiconductor device layouts to identify and implement optimal layout 205. A layout model (that indicates optimal layouts for semiconductor devices) may be generated during the iterative process of generating and running simulations. A meta-model (that indicates a mathematical model of dependence of semiconductor device performance on its input variables) may be generated during the iterative process. As explained herein, the AI/ML techniques may be used as part of controlling the iteration process, for identifying optimal layout 205, and for generating the meta-model. For example, the AI/ML techniques may be used as part of smart sampling of input variables for various iterations. The AI/ML techniques may include polynomial regression (also referred to as polynomials), kriging, genetic aggregation of response surface (GARS), and support vector regression (SVR), without limitation. In some examples, the model may be generated using one or more of the AI/ML techniques that best fit data (e.g., parameters 207). Optimal layout 205 may be provided to semiconductor manufacturing facility 217, which may include machinery and/or systems that manufacture or fabricate one or more semiconductor devices 219 based on optimal layout 205. In other words, ALDS 203 may provide optimal layout 205 to semiconductor manufacturing facility 217 to cause (or instruct) semiconductor manufacturing facility 217 to manufacture or fabricate one or more semiconductor devices 219 based on optimal layout 205. In some examples, semiconductor manufacturing facility 217 manufacture or fabricate one or more semiconductor devices 219 based on the attributes of optimal layout 205. In some instances, the optimal layout 205 and/or the generated meta-model of the semiconductor device may be used as part of a design process (e.g., may be used to guide or inform design teams) so that an optimal layout is included as a sub-part of a larger semiconductor design layout along with other semiconductor component design layouts. The larger semiconductor design layout may be provided to semiconductor manufacturing facility 217 to cause (or instruct) one or more larger semiconductor devices including optimal layout 205 to be manufactured or fabricated.

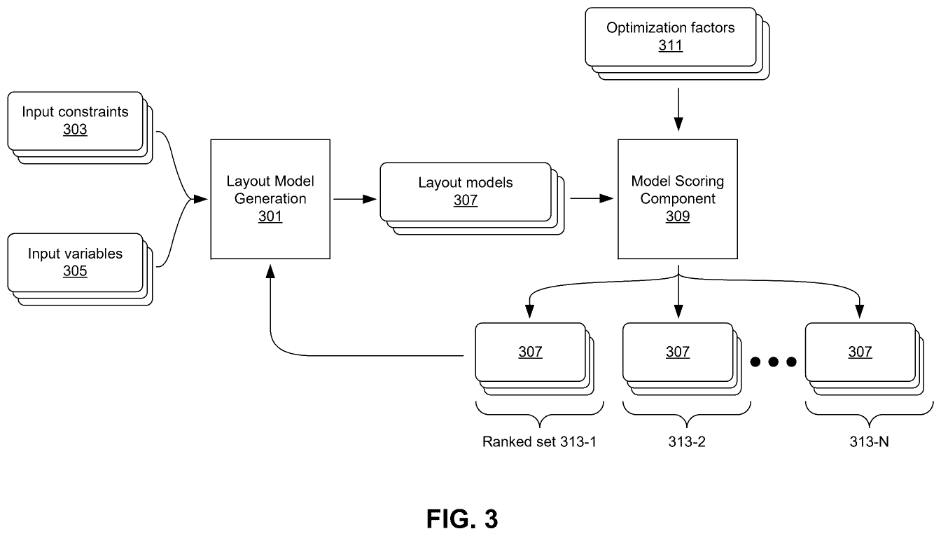

FIG. 3 illustrates an example of operations that may be performed by ALDS 203 in order to generate optimal layout 205. As shown, Layout Model Generation component 301 (e.g., which may be a component of ALDS 203) may receive a set of input constraints 303 and a set of input variables 305.

Input constraints 303 may include attributes or parameters that are not able to be changed or modified by Layout Model Generation component 301. On the other hand, input variables 305 may include an identification of attributes or parameters that may be modified or refined by Layout Model Generation component 301 using AI/ML techniques or other suitable techniques. In accordance with some implementations, input constraints 303 may include, for example, one or more component specification 201, and input variables 305 may indicate that parameters such as aspect ratio, pad configuration, and routing topology are able to be varied or changed by Layout Model Generation component 301.

Layout model generation component 301 may generate one or more layout models 307 (e.g., using AI/ML modeling techniques or other suitable techniques). In some examples, Layout Model Generation component 301 may implement an EDA tool that generates one or more layout models 307 and/or optimal layout 205. For example, the EDA tool may generate layout models (e.g., layout models 307) for a given set of input variables (e.g., input variables 305 such as area, length, among other examples). As explained herein, the AI/ML techniques may include polynomial regression, kriging, GARS, and SVR, without limitation. In some examples, layout model generation component 301 may generate the one or more layout models 307 using a scripting language (also referred to as “layout generating script”), as explained herein. As similarly discussed with respect to optimal layout 205, each layout model 307 may be associated with a respective set of parameters, which may include different values for some or all of the input variables 305, such as aspect ratio, pad configuration, a routing topology. Each layout model 307 may also be associated with a respective measure of resistance (e.g., Ron). In some examples, the set of parameters of a layout model 307 may be referred to as an input of the layout model 307 while the measure of resistance for the layout model 307 maybe referred to as an output of the layout model 307.

In some examples, each layout model 307 may be analyzed. For example, as part of analyzing a layout model 307, the layout model 307 may be scored and ranked. As an example, Model Scoring Component 309 (e.g., which may be a component of ALDS 203) may score each layout model 307 based on one or more optimization factors 311. In some examples, resistance (e.g., Ron) may be a factor to be optimized, which may include minimizing resistance, identifying a particular layout model 307 that exhibits a particular amount or range of resistance, and/or otherwise optimizing the resistance of a semiconductor device that implements a given layout model 307. Model Scoring Component 309 may, for example, simulate the operation of a semiconductor device that implements each given layout model 307 in order to identify the measure of resistance (e.g., Ron) for each layout model 307. In other examples, one or more other optimization factors 311, or combinations of optimization factors 311, may be used to score layout models 307. Such optimization factors 311 may include temperature of a semiconductor device that implements a given layout model 307, power consumption of a semiconductor device that implements a given layout model 307, and/or other factors which may be sought to be optimized.

Model Scoring Component 309 may, for example, generate one ranked set 313-1 of layout models 307 based on one optimization factor 311 (or set of optimization factors 311), may generate another ranked set 313-2 of layout models 307 based on another optimization factor 311 (or set of optimization factors 311), may generate yet another ranked set 313-N of layout models 307 based on one optimization factor 311 (or set of optimization factors 311), and so on. In this example, assume that ranked set 313-1 has been optimized based on resistance (e.g., Ron). In some implementations, the same layout model 307 may be associated with multiple different scores with respect to different optimization factors 311. For example, a given layout model 307 may be associated with one score that has been generated based on one optimization factor 311 (or set of optimization factors 311), another score that has been generated based on another optimization factor 311 (or set of optimization factors 311), and so on.

A highest scoring layout model 307, in ranked set 313-1, may be, for example, a particular layout model 307 that exhibits a lowest measure of resistance (e.g., Ron) out of the generated layout models 307. In some implementations, the highest scoring layout model 307 of a given ranked set 313 may be selected as an optimal layout 205, at least with respect to the optimization factor (or factors) 311 used to score, rank, or evaluate layout models 307 for the given ranked set 313. In some examples, Model Scoring Component 309 may implement an EDA tool that analyzes (e.g., scores, ranks, or evaluates) layout models 307. The EDA tool may take a layout model 307 as input and may simulate and analyze the layout model 307 to extract outputs or performance optimization factors (311 e.g. Ron). For example, layout models 307 may be analyzed as described herein. In some examples, Model Scoring Component 309 may analyze (e.g., score, rank, or evaluate) layout models 307 using a scripting language. In some examples, the scripting language may include a Perl script. In some implementations, the scripting language may be used to generate configuration files for the EDA tools that generate and analyze layout models 307. In some examples, an output of the EDA tool (that generates optimal layout 205 and/or layout models 307) may be provided as an input to the EDA tool that analyzes layout models 307. For example, a layout model 307 (e.g., the output of the EDA tool that generates layout models) may be provided as the input to the EDA tool that analyzes layout models. In some implementations, ALDS 203 may accordingly select the highest scoring layout model 307, from a given ranked set 313 that is associated with a particular optimization factor 311 or set of optimization factors 311 (e.g., resistance in some examples), as the optimal layout 205 when given input constraints 303 (e.g., component specification 201) and input variables 305.

In some implementations, Layout Model Generation component 301 and Model Scoring Component (309) may be run one after another multiple times in an iterative manner. In some implementations these iterations may be controlled by AI/ML algorithms which sample or determine input variables (305) for subsequent iterations based on results of prior iterations. For example, Layout Model Generation component 301 may continue to refine attributes of layout models 307 in order to generate additional layout models 307. For example, Layout Model Generation component 301 may identify a relatively high scoring layout model 307 (e.g., with respect to one or more optimization factors 311), and may iteratively generate a new layout model 307 that is based on the identified high scoring layout model 307. Iteratively generating the new layout model 307 may include adjusting (e.g., marginally or slightly adjusting) one or more parameters of the high scoring layout model 307 in order to attempt to generate an even higher scoring layout model 307, which would be considered even more optimal. In some instances, the AI/ML algorithms are also able to generate a meta-model of the semiconductor device. The meta-models represent a simplified relationship of one or more optimization factors 311 on one or more input variables 305. For example, a meta-model can be a mathematical relation or algorithm representing input and output relations (e.g., Ron=Function(length)).

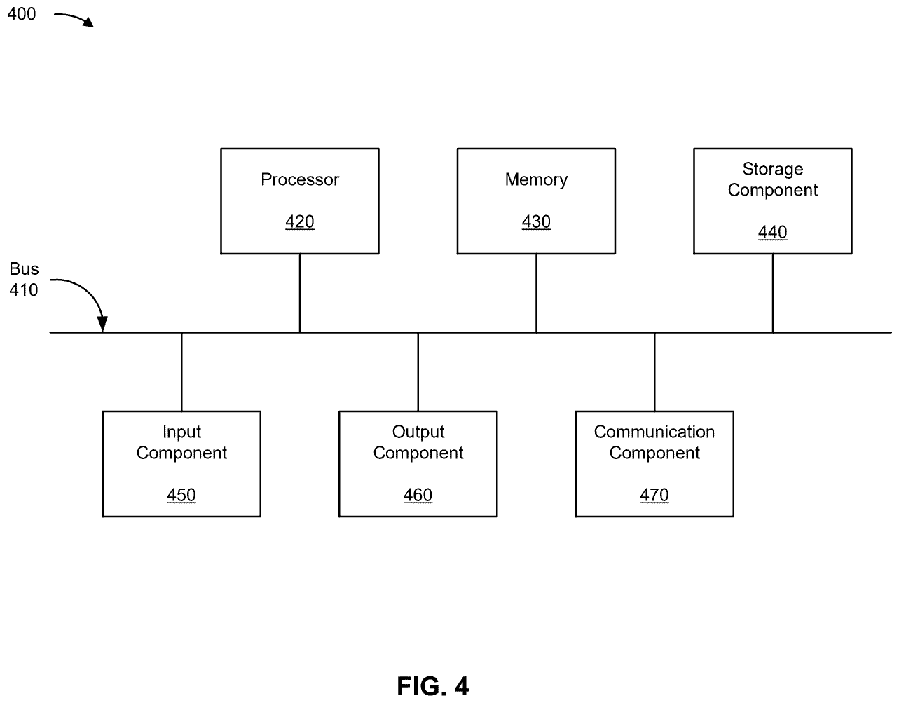

FIG. 4 is a diagram of example components of a device 400, which may be used to generate a layout of a semiconductor device in accordance with some implements described herein. In some implementations, ALDS 203, semiconductor manufacturing facility 217, Layout Model Generation component 301, and/or Model Scoring Component 309 may include one or more devices 400 and one or more components of device 400. As shown in FIG. 4, device 400 may include bus 410, processor 420, memory 430, storage component 440, input component 450, output component 460, and communication component 470.

Bus 410 includes a component that enables wired or wireless communication among the components of device 400. Processor 420 includes a central processing unit, a graphics processing unit, a microprocessor, a controller, a microcontroller, a digital signal processor, a field-programmable gate array, an application-specific integrated circuit, or another type of processing component. Processor 420 is implemented in hardware, firmware, or a combination of hardware and software. In some implementations, processor 420 includes one or more processors capable of being programmed to perform a function. Memory 430 includes a random access memory, a read only memory, or another type of memory (e.g., a flash memory, a magnetic memory, or an optical memory).

Storage component 440 stores information or software related to the operation of device 400. For example, storage component 440 may include a hard disk drive, a magnetic disk drive, an optical disk drive, a solid state disk drive, a compact disc, a digital versatile disc, or another type of non-transitory computer-readable medium. Input component 450 enables device 400 to receive input, such as user input or sensed inputs. For example, input component 450 may include a touch screen, a keyboard, a keypad, a mouse, a button, a microphone, a switch, a sensor, a global positioning system component, an accelerometer, a gyroscope, or an actuator. Output component 460 enables device 400 to provide output, such as via a display, a speaker, or one or more light-emitting diodes. Communication component 470 enables device 400 to communicate with other devices, such as via a wired connection or a wireless connection. For example, communication component 470 may include a receiver, a transmitter, a transceiver, a modem, a network interface card, or an antenna.

Device 400 may perform one or more processes described herein. For example, a non-transitory computer-readable medium (e.g., memory 430 or storage component 440) may store a set of instructions (e.g., one or more instructions, code, software code, or program code) for execution by processor 420. Processor 420 may execute the set of instructions to perform one or more processes described herein. In some implementations, execution of the set of instructions, by one or more processors 420, causes the one or more processors 420 or the device 400 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

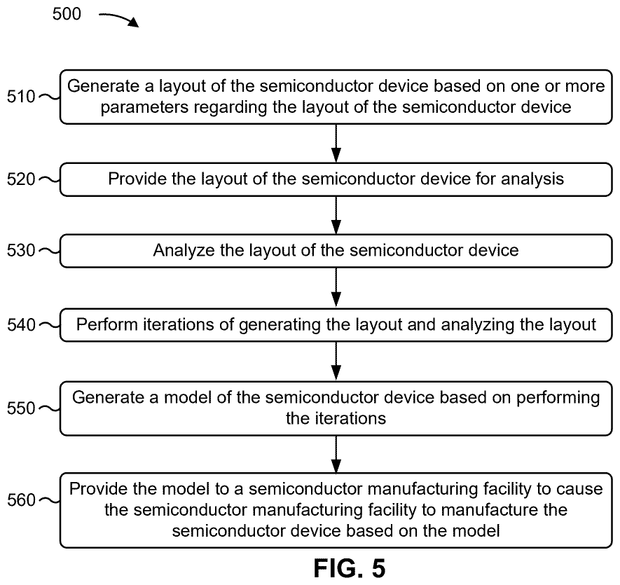

FIG. 5 is a flowchart of an example process 500 associated with generating and analyzing a layout of a semiconductor device as described herein. In some implementations, one or more process blocks of FIG. 5 may be performed by a device, such as ALDS 203. Additionally, or alternatively, one or more process blocks of FIG. 5 may be performed by one or more components of device 400, such as processor 420, memory 430, storage component 440, input component 450, output component 460, and/or communication component 470.

As shown in FIG. 5, process 500 may include generating a layout of the semiconductor device based on one or more parameters regarding the layout of the semiconductor device (block 510). For example, the device may generate a layout of the semiconductor device based on one or more parameters regarding the layout of the semiconductor device, as described above in connection with FIG. 3 (e.g., layout models 307).

As further shown in FIG. 5, process 500 may include providing the layout of the semiconductor device for analysis (block 520). For example, the device may provide the layout of the semiconductor device for analysis, as described above in connection with FIG. 3 (e.g., Model Scoring Component 309).

As further shown in FIG. 5, process 500 may include analyzing the layout of the semiconductor device (block 530). For example, the device may analyze the layout of the semiconductor device, as described above in connection with FIG. 3 (e.g., Model Scoring Component 309).

As further shown in FIG. 5, process 500 may include performing iterations of generating the layout and analyzing the layout (block 540). For example, the device may perform iterations of generating the layout and analyzing the layout, as described above in connection with FIG. 3. In some implementations, the one or more parameters are a first value during a first iteration of the iterations. In some implementations, the one or more parameters are a second value during a second iteration of the iterations.

As further shown in FIG. 5, process 500 may include generating a model of the semiconductor device based on performing the iterations (block 550). For example, the device may generate a model of the semiconductor device based on performing the iterations, as described above in connection with FIG. 2 (e.g., optimal layout 205).

As further shown in FIG. 5, process 500 may include providing the model of the semiconductor device to a semiconductor manufacturing facility to cause the semiconductor manufacturing facility to manufacture the semiconductor device based on the model (block 560). For example, the device may provide the model of the semiconductor device to the semiconductor manufacturing facility to cause the semiconductor manufacturing facility to manufacture the semiconductor device based on the model, as described above in connection with FIG. 2 (e.g., semiconductor manufacturing facility 217). In some examples, the semiconductor manufacturing facility may manufacture the semiconductor device based on attributes of the model. The attributes of the model may include an aspect ratio attribute, a pad configuration attribute, a routing topology attribute, and/or a resistance attribute, among other examples.

In some implementations, the semiconductor device includes a power semiconductor device.

In some implementations, the one or more parameters include a dimension of the semiconductor device, wherein the input of the model includes the dimension of the semiconductor device, and wherein the output of the model includes a resistance of the semiconductor device.

In some implementations, the one or more parameters include a dimension of the semiconductor device, and wherein analyzing the layout of the semiconductor device comprise performing a simulation of an operation of the semiconductor device to determine a resistance of the semiconductor device based on the dimension of the semiconductor device.

In some implementations, generating the layout of the semiconductor device comprises generating the layout of the semiconductor device using a first script.

In some implementations, analyzing the layout of the semiconductor device comprises analyzing the layout of the semiconductor device using a second script.

In some implementations, generating the layout of the semiconductor device comprises generating the layout of the semiconductor device using a first tool.

In some implementations, analyzing the layout of the semiconductor device comprises analyzing the layout of the semiconductor device using a second tool.

In some implementations, process 500 includes providing an output of the first tool as an input of the second tool.

In some implementations, the model includes a meta-model.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with other claims in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
generating a layout of a semiconductor device based on one or more parameters regarding the layout of the semiconductor device;
analyzing the layout of the semiconductor device;
performing iterations of generating the layout and analyzing the layout,
wherein one or more values, of the one or more parameters, are a first value during a first iteration of the iterations, and
wherein the one or more values, of the one or more parameters, are a second value during a second iteration of the iterations;
generating a model of the semiconductor device based on performing the iterations; and
providing the model of the semiconductor device to a semiconductor manufacturing facility to cause the semiconductor manufacturing facility to manufacture the semiconductor device based on the model.

2. The method of claim 1, wherein the semiconductor device includes a power semiconductor device.

3. The method of claim 1, wherein the one or more parameters include a dimension of the semiconductor device, and
wherein an output of the model includes a resistance of the semiconductor device.

4. The method of claim 1, wherein the one or more parameters include a dimension of the semiconductor device, and
wherein analyzing the layout of the semiconductor device comprise:
performing a simulation of an operation of the semiconductor device to determine a resistance of the semiconductor device based on the dimension of the semiconductor device.

5. The method of claim 1, wherein generating the layout of the semiconductor device comprises:
generating the layout of the semiconductor device using a first script.

6. The method of claim 5, wherein analyzing the layout of the semiconductor device comprises:
analyzing the layout of the semiconductor device using a second script.

7. The method of claim 1, wherein generating the layout of the semiconductor device comprises:
generating the layout of the semiconductor device using a first tool.

8. The method of claim 7, wherein analyzing the layout of the semiconductor device comprises:
analyzing the layout of the semiconductor device using a second tool.

9. The method of claim 8, comprising:
providing an output of the first tool as an input of the second tool.

10. The method of claim 1, wherein the model includes a meta-model.

11. A system comprising:
one or more processing units adapted to:
generate a layout of a power semiconductor device based on one or more parameters regarding the layout of the power semiconductor device;
analyze the layout of the semiconductor device to determine a characteristic of the power semiconductor device;
perform iterations of generating the layout and analyzing the layout,
wherein one or more values, of the one or more parameters, are a first value during a first iteration of the iterations, and
wherein the one or more values, of the one or more parameters, are a second value during a second iteration of the iterations;
generate a model of the power semiconductor device based on performing the iterations; and
provide the model of the power semiconductor device to cause the power semiconductor device to be manufactured based on attributes of the model.

12. The system of claim 11, wherein a value, of the one or more parameters, changes during the iterations.

13. The system of claim 11, wherein the power semiconductor device includes a power metal oxide semiconductor field effect transistor (MOSFET).

14. The system of claim 11, wherein the one or more parameters include a dimension of the power semiconductor device, and
wherein an output of the model includes a resistance of the power semiconductor device.

15. The system of claim 11, wherein the one or more parameters include a dimension of the power semiconductor device, and
wherein, to analyze the layout of the power semiconductor device, the one or more processing units are to:
perform a simulation of an operation of the power semiconductor device to determine a resistance of the power semiconductor device based on the dimension of the semiconductor device.

16. The system of claim 11, wherein, to generate the layout of the power semiconductor device, the one or more processing units are to:
generate the layout of the semiconductor device using a first tool,
wherein, to analyze the layout of the power semiconductor device, the one or more processing units are to:
analyze the layout of the semiconductor device using a second tool, and
wherein the one or more processing units are to:
provide an output of the first tool as an input of the second tool.

17. A non-transitory computer-readable medium storing a set of instructions, the set of instructions comprising:
one or more instructions that, when executed by one or more processors of a computing device, cause the computing device to:
generate a layout of a semiconductor device based on one or more parameters regarding the layout of the semiconductor device;
analyze the layout of the semiconductor device;
perform iterations of generating the layout and analyzing the layout,
wherein one or more values, of the one or more parameters, are a first value during a first iteration of the iterations, and
wherein the one or more values, of the one or more parameters, are a second value during a second iteration of the iterations;
generate a model of the semiconductor device based on performing the iterations; and
provide the model to cause the semiconductor device to be manufactured based on the model.

18. The non-transitory computer-readable medium of claim 17, wherein the semiconductor device includes a power semiconductor device.

19. The non-transitory computer-readable medium of claim 17, wherein the one or more parameters include a dimension of the semiconductor device, and
wherein the output of the model includes a resistance of the semiconductor device.

20. The non-transitory computer-readable medium of claim 17, wherein the one or more parameters include a dimension of the semiconductor device, and
wherein the one or more instructions, that cause the computing device to analyze the layout of the semiconductor device, cause the computing device to:
perform a simulation of an operation of the semiconductor device to determine a resistance of the semiconductor device based on the dimension of the semiconductor device.
